(19) United States
(12) Patent Application Publication
(10) Pub. No.: US 2026/0317903 A1
(43) Pub. Date: Oct. 15, 2026

(54) AREA SELECTIVE DEPOSITION OF DIELECTRIC FILM ON SILICON CONTAINING SURFACES UTILIZING ALCOHOLS

(71) Applicants: Merck Patent GmbH, Darmstadt (DE); VERSUM MATERIALS US, LLC, Tempa, AR (US)

(72) Inventors: Lanxia Cheng, San Jose, CA (US); Tingmin Wang, Laguna Niguel, CA (US); Matthew R. MacDonald, Santa Margarita, CA (US); Po-Chun Liu, Kaohsiung City (TW); Bhushan Zope, San Jose, CA (US); Chang-Won Lee, Ansan-si (KR); Xinjian Lei, Vista, CA (US); Haripin Chandra, San Marcos, CA (US); Mahsa Konh, Carlsbad, CA (US)

(21) Appl. No.: 19/485,640

(22) PCT Filed: May 17, 2024
(86) PCT No.: PCT/US2024/030033

§ 371 Date: Nov. 18, 2025

Related U.S. Application Data
(60) Provisional application No. 63/503,415, filed on May 19, 2023.

(51) Int. Cl. C23C 16/455; C23C 16/04; C23C 16/40

(52) U.S. Cl. CPC C23C 16/45553; C23C 16/04; C23C 16/401; C23C 16/45534

(57) ABSTRACT

A method for selectively passivating a surface of a substrate, wherein the surface of the substrate includes at least a first surface comprising silicon nitride and at least a second surface comprising a material other than silicon nitride. The method includes the step of exposing the surface to at least one alcohol wherein the alcohol selectively reacts with the silicon nitride to passivate the first surface thereby leaving the second surface substantially unreacted.

### CROSS-REFERENCE TO RELATED APPLICATIONS

This application claims priority to U.S. Provisional Patent application No. 63/503,415 filed on May 19, 2023, which is hereby incorporated by reference in its entirety.

### FIELD

The present application relates to selective deposition on a first surface of a substrate relative to a second surface. In addition, further processing can be used to subsequently deposit a different material on the second surface relative to the first.

### BACKGROUND

Selective deposition processes are gaining a lot of momentum mostly because of the limitations of contemporary lithographic processes to enable the fabrication of advanced semiconductor devices based on ever diminishing physical dimensions. Traditionally, patterning in the microelectronics industry has been accomplished using various lithography and etch processes. However, since lithography is becoming exponentially more complex and expensive the use of selective deposition to form self-aligned features is becoming much more attractive. The fabrication of self-aligned via structures would benefit significantly from manufacturable selective deposition processes. Another potential application for selective deposition is gap fill. In gap fill, the dielectric “fill” film is grown selectively from the bottom of a trench towards the top. Selective deposition could be used for other applications such as selective sidewall deposition where films are selectively deposited on exposed surfaces of three dimensional FIN-FET structures. This would enable the deposition of a sidewall spacer without the need for complex patterning steps. Selective deposition processes for metal and metal oxide films that are used as gate dielectrics and capacitor dielectrics would also be of great utility in semiconductor device manufacturing.

There are previous examples within the technical literature related to the selective formation of surface passivation coatings on wafers with multiple, different chemical surfaces that are exposed. This has been done with the purpose of retarding or preventing the deposition of films through ALD processes on these passivated surfaces, but not preventing deposition on the surfaces where the ALD deposition process is desired to deposit a film. In general, the selectivity of the processes has been less than adequate due to incomplete passivation of the surfaces and/or due to physisorption of ALD precursor molecules and subsequent formation of the ALD film material either within the passivation layer itself or on the surfaces where deposition is not desired. The present disclosure seeks to overcome the limitations of the prior art and provide improved methods for selective deposition of thin film materials using ALD deposition processes.

Liu, L.-H. et al. J. Phys.: Condens. Matter 28 (2016) 094014 (doi:10.1088/0953-8984/28/9/094014) teach that silicon nitride might be selectively passivated to some extent relative to silicon oxide by treatment of a treated surface with a solution containing an aldehyde.

### SUMMARY

In a first aspect, a method is provided for selectively passivating a surface of a substrate, wherein the surface of the substrate comprises at least a first surface comprising silicon nitride and at least a second surface comprising a material other than silicon nitride, the method comprising the steps of: a. optionally, treating the surface with hydrogen plasma, argon plasma, or ammonia plasma; and b. exposing the surface to at least one alcohol having a structure according to Formula I: R—OH (I), wherein R is selected from the group consisting of a substituted or unsubstituted C₅ to C₁₈ linear alkyl group, a substituted or unsubstituted branched C₄ to C₁₈ alkyl group, a substituted or unsubstituted C₄ to C₈ cyclic alkyl group, a substituted or unsubstituted C₃ to C₁₀ heterocyclic group, a substituted or unsubstituted C₄ to C₁₈ alkenyl group, a substituted or unsubstituted C₄ to C₁₈ aryl group, a substituted or unsubstituted C₅ to C₂₀ arylalkyl group, and a substituted or unsubstituted C₄ to C₁₀ alkynyl group, and wherein the at least one alcohol selectively reacts with the silicon nitride to passivate the first surface thereby leaving the second surface substantially unreacted; and c. depositing a dielectric film onto the substrate via atomic layer deposition.

In a further aspect of the first main aspect, the following steps which are performed prior to steps a and b: contacting the surface of the substrate with a wet chemical composition; rinsing the surface with deionized water; and drying the surface, wherein the wet chemical composition comprises at least one selected from the group consisting of a composition comprising H₂O₂(28% aq.), NH₄O₄(28-30%), and H₂O; HF (0.01%-5% (aq.)); peroxide; RCA clean chemicals SC-1 and SC-2; and a mixture of H₂SO₄/H₂O₂. In a further aspect of the first main aspect, the second surface comprises at least one selected from the group consisting of SiO₂, carbon doped silicon oxide, a metal oxide, copper, cobalt, tungsten, amorphous silicon, polysilicon, monocrystalline silicon, germanium, and amorphous hydrogenated germanium. In a further aspect of the first main aspect, the second surface comprises SiO₂ or carbon doped silicon oxide. In a further aspect of the first main aspect, the at least one alcohol is a C₅ to C₁₈ linear alkyl group having a structure CₙH₂ₙ₊₁, wherein n is 5 to 18. In a further aspect of the first main aspect, the at least one alcohol is a linear C₈ to C₁₈ alcohol selected from the group consisting of 1-octanol, 1-nonanol, 1-decanol, 1-undecanol, 1-dodecanol, 1-tridecanol, 1-tetradecanol, 1-pentadecanol, 1-hexadecanol, 1-heptadecanol, 1-octadecanol, 8-chloro-1-octanol, and pentadecafluoro-1-octanol. In a further aspect of the first main aspect, R is a branched C₄ to C₁ alkyl group having a formula CₙH₂ₙ₊₁, wherein n is 4 to 18. In a further aspect of the first main aspect, the at least one alcohol is selected from the group consisting of iso-butyl alcohol, iso-pentyl alcohol, iso-hexyl alcohol, iso-heptyl alcohol, iso-octyl alcohol, iso-nonyl alcohol, iso-decyl alcohol, iso-undecyl alcohol, iso-dodecyl alcohol, iso-tridecyl alcohol, iso-tetradecyl alcohol, iso-pentadecyl alcohol, iso-hexadecyl alcohol, iso-heptadecyl alcohol, and iso-octadecyl alcohol. In a further aspect of the first main aspect, R is a substituted or unsubstituted C₃ to C₈ cyclic alkyl group. In a further aspect of the first main aspect, the at least one alcohol is selected from the group consisting of cyclopropyl alcohol, cyclobutyl alcohol, cyclopentyl alcohol, cyclohexyl alcohol, cycloheptyl alcohol, cyclooctyl alcohol, and 1-methyl cyclohexanol. In a further aspect of the first main aspect, R comprises a substituted or unsubstituted C₄ to C₁₈ aryl group. In a further aspect of the first main aspect, the at least one alcohol is selected from the group consisting of phenol, p-cresol, 4-methyphenol, 4-ethylphenol, 4-n-propylphenyl, 4-iso-propylphenyl, 4-n-butylphenyl, 4-sec-butylphenyl, 4-iso-butylphenyl, 4-trifluoromethylphenol, 4-n-octyl-phenol, 4-n-pentyl-phenol, and 4-hexyl-phenol. In a further aspect of the first main aspect, R is an unsubstituted C₈ to C₁₈ linear alkyl group or R is a substituted or unsubstituted branched C₃ to C₁₈ alkyl group. In a further aspect of the first main aspect, the at least one alcohol is selected from the group consisting of 1-octanol, 1-nonanol, 1-decanol, 1-undecanol, 1-dodecanol, 1-tridecanol, 1-tetradecanol, 1-pentadecanol, 1-hexadecanol, 1-heptadecanol, 1-octadecanol, 8-chloro-1-octanol, pentadecafluoro-1-octanol, iso-butyl alcohol, iso-pentyl alcohol, iso-hexyl alcohol, iso-heptyl alcohol, iso-octyl alcohol, iso-nonyl alcohol, iso-decyl alcohol, iso-undecyl alcohol, iso-dodecyl alcohol, iso-tridecyl alcohol, iso-tetradecyl alcohol, iso-pentadecyl alcohol, iso-hexadecyl alcohol, iso-heptadecyl alcohol, and iso-octadecyl alcohol. In a further aspect of the first main aspect, R is a substituted or unsubstituted C₅ to C₂₀ arylalkyl group. In a further aspect of the first main aspect, the at least one alcohol is benzyl alcohol. In a further aspect of the first main aspect, step b. is conducted with a vapor of the at least alcohol.

In a second main aspect, a method is provided for selectively depositing a film on a surface of a substrate wherein the surface of the substrate comprises at least a first surface comprising silicon nitride and at least a second surface comprising a material other than silicon nitride, the method comprising the steps of: a. optionally, treating the surface with hydrogen plasma or ammonia plasma; b. exposing the surface to at least one alcohol having a structure according to Formula I: R—OH (I), wherein, R is selected from the group consisting of a substituted or unsubstituted C₅ to C₁₈ linear alkyl group, a substituted or unsubstituted branched C₂ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, wherein the at least one alcohol selectively reacts with the silicon nitride to passivate the first surface thereby leaving the second surface substantially unreacted; and c. exposing the surface of the substrate to one or more deposition precursors to deposit a dielectric film on the second surface selectively over the first surface.

In a further aspect of the second main aspect, the method further comprises the following steps which are performed prior to steps a and b and c: contacting the surface of the substrate with a wet chemical composition; rinsing the surface with deionized water; and drying the surface, wherein the wet chemical composition comprises at least one selected from the group consisting of a composition comprising H₂O₂(28% aq), NH₄O₄(28-30%), and H₂O; HF (0.01%-5% (aq)); peroxide; RCA clean chemicals SC-1 and SC-2; and a mixture of H₂SO₄/H₂O₂. In a further aspect of the second main aspect, the second surface comprises at least one selected from the group consisting of SiO₂, carbon doped silicon oxide, a metal oxide, copper, cobalt, ruthenium, tungsten, molybdenum, amorphous silicon, polysilicon, monocrystalline silicon, germanium, and amorphous hydrogenated germanium. In a further aspect of the second main aspect, the second surface comprises SiO₂ or carbon doped silicon oxide. In a further aspect of the second main aspect, the at least one alcohol is a Cₑ to C₁₈ linear alkyl group having a structure CₙH₂ₙ₊₁—OH, wherein n is 8 to 18. In a further aspect of the second main aspect, the at least one alcohol is selected from the group consisting of 1-octanol, 1-nonanol, 1-decanol, 1-undecanol, 1-dodecanol, 1-tridecanol, 1-tetradecanol, 1-pentadecanol, 1-hexadecanol, 1-heptadecanol, 1-octadecanol, 8-chloro-1-octanol, and pentadecafluoro-1-octanol. In a further aspect of the second main aspect, the dielectric film comprises TiO₂, HfO₂, ZrO₂, Al₂O₃ Ta₂O₅, SiC₂ or combinations thereof. In a further aspect of the second main aspect, R is a substituted or unsubstituted C₃ to C₈ cyclic alkyl group. In a further aspect of the second main aspect, the at least one alcohol is selected from the group consisting of cyclopropyl alcohol, cyclobutyl alcohol, cyclopentyl alcohol, cyclohexyl alcohol, cycloheptyl alcohol, cyclooctyl alcohol, 1-methyl-cyclohexanol, 2-methylcyclohexyl alcohol, 3-methylcyclohexyl alcohol, and 4-methylcyclohexyl alcohol. In a further aspect of the second main aspect, R is a substituted or unsubstituted C₄ to C₁₈ aryl group. In a further aspect of the second main aspect, the at least one alcohol is selected from the group consisting of phenol, tolyl alcohol, dimethylphenol, and xylyl alcohol. In a further aspect of the second main aspect, R is an unsubstituted C₅ to C₁₈ linear alkyl group or R is a substituted or unsubstituted branched C₃ to C₁₈ alkyl group.

In a further aspect of the second main aspect, the at least one alcohol is selected from the group consisting of tert-hexyl alcohol, n-heptyl alcohol, sec-heptyl alcohol, tert-heptyl alcohol, n-octyl alcohol, sec-octyl alcohol, tert-octyl alcohol, n-nonanol, sec-nonanol, tert-nonanol, n-decanol, sec-decanol, tert-decanol, n-undecanol, sec-undecanol, tert-undecanol, n-dodecanol, sec-dodecanol, tert-dodecanol, n-tridecanol, sec-tridecanol, tert-tridecanol, n-tetradecanol, sec-tetradecanol, tert-tetradecanol, n-pentadecanol, sec-pentadecanol, tert-pentadecanol, n-hexadecanol, sec-hexadecanol, tert-hexadecanol, n-heptadecanol, sec-heptadecanol, tert-heptadecanol, n-octadecanol, sec-octadecanol, tert-octadecanol, 1,1,3,3-tetramethylbutyl alcohol, and 1-methylheptyl alcohol. In a further aspect of the second main aspect, R is a substituted or unsubstituted C₅ to C₂₀ arylalkyl group.

In a further aspect of the second main aspect, the at least one alcohol is selected from the group consisting of phenylmethanol, 2-phenyl-1-ethanol, 3-phenyl-1-propanol, 4-phenyl-1-butanol, 5-phenyl-1-pentanol, 6-phenyl-1-hexanol, 7-phenyl-1-heptanol, 8-phenyl-1-octanol.

In a further aspect of the second main aspect, the at least one alcohol is benzyl alcohol. In a further aspect of the second main aspect, step b. is conducted with a vapor of the at least one alcohol. In a further aspect of the second main aspect, step b. is conducted with a liquid of the at least one alcohol. In a further aspect of the second main aspect, step b. is conducted with a liquid of the at least one alcohol.

In a further aspect of the first main aspect or the second main aspect, the alcohol is selected from the group consisting of isopropanol, 1-methylcyclohexanol, 8-chloro-1-octanol, phenol, 1-octanol, 2,2,3,3,4,4,5,5,6,6,7,7,8,8,8-pentadecafluoro-1-octanol, 1-undecanol, and 1-dodecanol. In a further aspect of the first main aspect or the second main aspect, the R in formula (I) is R′—CH₂, wherein R′ is chosen from the group consisting of linear C₇ to C₁₇ alkyl groups, branched C₆ to C₁₆ alkyl groups, and C₆ to C₁₀ aryl groups.

In a further aspect of the first main aspect or the second main aspect, a thickness of dielectric film deposited on the first surface is less than a thickness of dielectric film deposited on the second surface; wherein the second surface comprises silicon dioxide; and wherein a deposition selectivity of the second surface to the first surface is greater than about 0.1, more preferably greater than about 0.2, and most preferably greater than about 0.3. In a further aspect of the first main aspect or the second main aspect, R comprises a fluorine-substituted C₄ to C₁₈ linear alkyl group having a structure CₙF₂ₙ₊₁CH₂—OH, wherein n is 1 to 17. In a further aspect of the first main aspect or the second main aspect, the at least one alcohol is selected from the group consisting of C₃F₇CH₂—OH, C₄F₉CH₂—OH, C₅F₁₁CH₂—OH, C₆F₁₃CH₂—OH, C₇F₁₅CH₂—OH, C₃F₁₇CH₂—OH, and C₉F₁₉CH₂—OH. In a further aspect of the first main aspect or the second main aspect, R is a chlorine-substituted C₁ to C₁₈ linear alkyl group having a structure CₙCl₂ₙ₊₁CH₂—OH, wherein n is 1 to 17. In a further aspect of the first main aspect or the second main aspect, the at least one alcohol is selected from the group consisting of CCl₃CH₂—OH, C₂C₁₅CH₂—OH, C₃C₁₇CH₂—OH, C₄C₁₉CH₂—OH, C₅Cl₁₁CH₂—OH, C₆Cl₁₃CH₂—OH, C₇Cl₁₅CH₂—OH, C₃Cl₁₇CH₂—OH, C₉Cl₁₉CH₂—OH, and 8-chloro-1-octanol.

The embodiments of the disclosure can be used alone or in combinations with each other.

### BRIEF DESCRIPTION OF DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates a process of passivating a silicon nitride surface and depositing a film on a silicon dioxide surface;

FIG. 2 illustrates data regarding dielectric film deposition conducted after passivating with different inhibitors;

FIG. 3 illustrates the effect of annealing prior to depositing a dielectric layer;

FIG. 4 illustrates data regarding saturation of 1-butanol and 1-octanol on silicon nitride surface; and

FIG. 5 illustrate silicon oxide deposition on passivated silicon nitride surfaces with 1-butanol and 1-octanol.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosure (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosure and does not pose a limitation on the scope of the claims unless otherwise stated explicitly. No language in the specification should be construed as indicating any non-claimed element as essential to the practice of the subject matter of this disclosure.

Preferred embodiments of this disclosure are described herein, including the best mode known to the inventors for carrying out the claimed subject matter. Variations of those preferred embodiments may become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the claimed subject matter unless otherwise indicated herein or otherwise clearly contradicted by context.

There are a variety of methods that could be used for selective depositions. Embodiments of the disclosure are directed to methods that employ surface deactivation by taking advantage of the surface chemistry of two different surfaces. Since two different surfaces will have different reactive handles, the differences can be taken advantage of by utilizing molecules that will react with one surface (to deactivate that surface) and not react with the other surface.

In one embodiment, there is provided a method for selectively passivating a surface of a substrate by vapor phase reaction, wherein the surface of the substrate comprises at least a first surface comprising silicon nitride and at least a second surface comprising a material other than the silicon nitride, the method comprising the steps of: a. contacting the surface of the substrate with a wet chemical composition; b. rinsing the surface with deionized water; c. drying the surface; d. optionally, treating the surface with hydrogen plasma, argon plasma, or ammonia plasma; and e. exposing the surface to at least one alcohol having a structure according to Formula I: R—OH, wherein, R is selected from the group consisting of a substituted or unsubstituted C₅ to C₁₈ linear alkyl group, a substituted or unsubstituted branched C₃ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, and wherein the at least one alcohol selectively reacts with the silicon nitride to passivate the first surface thereby leaving the second surface substantially unreacted.

In another embodiment, there is provided a method for selectively passivating a surface of a substrate by liquid phase reaction, wherein the surface of the substrate comprises at least a first surface comprising silicon nitride and at least a second surface comprising a material other than the silicon nitride, the method comprising the steps of: a. contacting the surface of the substrate with a wet chemical composition; b. rinsing the surface with deionized water; c. drying the surface; d. optionally, treating the surface with hydrogen plasma, argon plasma, or ammonia plasma; and e. exposing the surface to at least one alcohol having a structure according to Formula I: R—OH, wherein, R is selected from the group consisting of a substituted or unsubstituted C₅ to C₁₈ linear alkyl group, a substituted or unsubstituted branched C₃ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, and wherein the at least one alcohol selectively reacts with the silicon nitride to passivate the first surface thereby leaving the second surface substantially unreacted.

In another embodiment, there is provided a method of selectively depositing a film on a surface of a substrate wherein the surface of the substrate comprises at least a first surface comprising silicon nitride and at least a second surface comprising a material other than the silicon nitride, the method comprising the steps of: a. contacting the surface of the substrate with a wet chemical composition; b. rinsing the surface with deionized water; c. drying the surface; d. optionally, treating the surface with hydrogen plasma or ammonia plasma; e. exposing the surface to at least one alcohol having a structure according to Formula I: R—OH, wherein, R is selected from the group consisting of a substituted or unsubstituted C₅ to C₁₈ linear alkyl group, a substituted or unsubstituted branched C₃ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, and wherein the at least one alcohol selectively reacts with the silicon nitride to passivate the first surface thereby leaving the second surface substantially unreacted; and f. exposing the substrate to one or more deposition precursors to deposit a film on the second surface selectively over the first surface.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used. In one or more embodiments, the first substrate surface will comprise a metal, and the second substrate surface will comprise a dielectric, or vice versa. In some embodiments, a substrate surface may comprise certain functionality (e.g., —OH, —NH, etc.).

Likewise, the films that can be used in the methods described herein are quite varied. In some embodiments, the films may comprise, or consist essentially of a metal or metal nitride. Examples of metal films include, but are not limited to, ruthenium (Ru), cobalt (Co), copper (Cu), titanium, (Ti), tantalum (Ta), nickel (Ni), tungsten (W), molybdenum (Mo), etc., and combinations thereof. Examples of metal nitride films include, but are not limited to, tantalum nitride (TaN), titanium nitride (TiN), tungsten nitride (WN), tungsten carbonitride (WCN), molybdenum nitride (MoN), copper silicon nitride (CuSiN), etc., and combinations thereof. In some embodiments, the film comprises a dielectric. Examples include, SiO₂, carbon doped silicon oxide, SiN, HfO₂, etc.

In embodiments of the present disclosure, the substrate has at least two discrete surfaces wherein each discrete surface is characterized by a different chemistry. For example, in an embodiment, the surface of the substrate comprises at least a first surface comprising silicon nitride and at least a second surface comprising a material other than silicon nitride.

The at least one second surface comprising a material other than silicon nitride can be, for example, any of the materials selected from the group consisting of SiO₂, carbon doped silicon oxide, a metal oxide, copper, cobalt, tungsten, amorphous silicon, polysilicon, monocrystalline silicon, germanium, and amorphous hydrogenated germanium. In some embodiments the at least one second surface comprises SiO₂ is a dielectric surface, such as a SiO₂ surface. In some embodiments the surface comprising SiO₂ may comprise silicon oxides, fluorinated silica glass (FSG), carbon doped silicon oxide (SiOC) and/or materials containing more than about 50% silicon oxide. In some embodiments the surface comprising SiO₂ comprises —OH groups and may also comprise, for example, an alumina (Al₂O₃) surface with —OH surface groups.

Embodiments of the disclosure provide methods of selectively depositing a film such as, for example, a metal film, onto one surface of a substrate over a second surface on the same substrate. As used in this specification and the appended claims, the term “selectively depositing a film on one surface over another surface,” and the like, means that one of the first or second surface is passivated to substantially prevent deposition on the passivated layer and a film is deposited on the second (non-passivated) surface. The term “over” used in this regard does not imply a physical orientation of one surface on top of another surface, rather a relationship of the thermodynamic or kinetic properties of the chemical reaction with one surface relative to the other surface. For example, selectively depositing a cobalt film onto a copper surface over a dielectric surface means that the cobalt film deposits on the copper surface and less or no cobalt film deposits on the dielectric surface; or that the formation of the cobalt film on the copper surface is thermodynamically or kinetically favorable relative to the formation of a cobalt film on the dielectric surface.

In some situations, it is desirable to selectively deposit a material on one surface of a substrate relative to a second, different surface of the same substrate. For example, selective deposition may be used to form capping layers, barrier layers, etch stop layers, sacrificial and/or protective layers or for sealing pores, such as in porous low k materials.

The method of the present disclosure includes the optional step of contacting the surface of the substrate with a wet chemical composition to obtain a treated substrate. Exemplary wet chemical treatments include known chemical treatments such as, for example, RCA clean chemicals SC-1 and SC-2, aqueous HF, peroxide, H₂SO₄/H₂O₂, NH₄OH, buffered HF solutions, and mixtures thereof.

In preferred embodiments, the wet chemical composition comprises at least one selected from the group consisting of a composition comprising H₂O₂(28% aq.), NH₄O₄(28-30%), and H₂O; HF (0.01%-10% (aq.)); peroxide; RCA clean chemicals SC-1 and SC-2; and a mixture of H₂SO₄/H₂O₂.

As is known in the art, “RCA clean chemicals” refer to compositions comprising an ammonium hydroxide and hydrogen peroxide mixture wherein the basic cleaning procedure developed by the Radio Corporation of America in the 1960s. The RCA Standard-Clean-1 (SC-1) procedure uses an ammonium hydroxide and hydrogen peroxide solution and water heated to a temperature of about 70° C. The SC-1 procedure dissolves films and removes Group I and II metals. The Group I and II metals are removed through complexing with the reagents in the SC-1 solution. The RCA Standard-Clean-2 (SC-2) procedure utilizes a mixture of hydrogen peroxide, hydrochloric acid, and water heated to a temperature of about 70° C. The SC-2 procedure removes the metals that are not removed by the SC-1 procedure.

Contacting with the wet chemical composition can occur by any method known to those skilled in the art such as, for example, dipping or spraying. The contacting step can be one discrete step or more than one step.

In some embodiments, the temperature of the wet chemical composition during the contacting step can be, for example, from about ambient temperature to about 100° C. In other embodiments, the temperature of the wet chemical composition during the contacting step can be, for example, from about 55° C. to about 95° C. In other embodiments, the temperature of the wet chemical composition during the contacting step can be, for example, from about 60° C. to about 90° C.

Embodiments also include the step of rinsing the surface of the substrate with deionized water after the step of contacting the surface of the substrate with the wet chemical composition. The rinsing step is typically carried out by any suitable means, for example, rinsing the surface of the substrate with de-ionized water by immersion or spray techniques.

Embodiments also include the step of drying at least the surface of the substrate after the rinsing step. The drying step is typically carried out by any suitable means, for example, the application of heat, isopropyl alcohol (IPA) vapor drying, or by centripetal force.

Embodiments also optionally include the step of treating the surface with hydrogen plasma, argon plasma, or ammonia plasma. Suitable processes include plasma processes (hydrogen plasma, NH₃/NF₃ plasmas, water plasmas, and the like). The optional plasma step functions to remove undesired deposits on the surface and activate the surface for subsequent deposition of passivation reagents. Such plasma treatments may be most preferably applied after some deposition on the surface has been performed in order to remove non-selectively deposited material from the previously passivated surface and to remove residual passivation reagents after the desired deposition thickness has been achieved.

Embodiments include the step of exposing the surface to a vapor or liquid comprising at least one alcohol having a structure according to Formula I:

R—OH (I),

wherein, R is selected from the group consisting of a substituted or unsubstituted C₅ to C₁₈ linear alkyl group, a substituted or unsubstituted branched C₃ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, wherein the at least one alcohol selectively reacts with the silicon nitride to passivate the first surface thereby leaving the second surface substantially unreacted.

This new family of passivation chemistries that can be used to achieve selective passivation of SiN over SiO2.

This new family of passivation chemistries shows better selective adsorption on SiN over SiO2 than state of art passivation chemistries reported.

This new family of passivation chemistries demonstrates better oxide deposition selectivity at 250° C.

This new family of passivation layer on SiN shows good thermal stability up to 250° C. and even higher.

This new passivation method has high potential for high temp. ASD applications.

In some embodiments, the alcohol is a C₅ to C₁₈ linear alkyl group having a structure selected from the group consisting of CₙH₂ₙ₊₁. Preferred alcohol precursors having a C₁ to C₁₈ linear alkyl group include those selected from the group consisting of 1-octanol, 1-nonanol, 1-decanol, 1-undecanol, and 1-dodecanol.

In other embodiments, R in Formula I is a C₃ to C₁₈ branched alkyl group. Preferred alcohol precursors having a branched alkyl group include those selected from the group consisting of isobutanol, and tertbutanol.

In other embodiments, R in Formula I is a substituted or unsubstituted C₃ to C cyclic alkyl group. In such embodiments, the at least one alcohol includes those selected from the group consisting of cyclopropyl alcohol, cyclobutyl alcohol, cyclopentyl alcohol, cyclohexyl alcohol, cycloheptyl alcohol, cyclooctyl alcohol, and 1-methyl cyclohexanol.

In other embodiments, R in Formula I is a substituted or unsubstituted C₄ to C₁₈ aryl group.

In other embodiments, R in Formula I is an unsubstituted C₅ to C₁₈ linear alkyl group or R is a substituted or unsubstituted branched C₅ to C₁₈ alkyl group.

In another embodiment, R in Formula I is a substituted or unsubstituted C₅ to C₂₀ arylalkyl group. In such embodiments, the alcohol includes benzyl alcohol.

As employed throughout the description, the term “alkyl” means a saturated hydrocarbon group which is straight-chained or branched. In some embodiments, the alkyl group has from 1 to 20 carbon atoms, from 2 to 20 carbon atoms, from 1 to 10 carbon atoms, from 2 to 10 carbon atoms, from 1 to 8 carbon atoms, from 2 to 8 carbon atoms, from 1 to 6 carbon atoms, from 2 to 6 carbon atoms, from 1 to 4 carbon atoms, from 2 to 4 carbon atoms, from 1 to 3 carbon atoms, or 2 or 3 carbon atoms. Examples of alkyl groups include, but are not limited to, methyl (Me), ethyl (Et), propyl (e.g., n-propyl and isopropyl), butyl (e.g., n-butyl, t-butyl, isobutyl), pentyl (e.g., n-pentyl, isopentyl, neopentyl), hexyl, isohexyl, heptyl, octyl, nonyl, 4,4dimethylpentyl, 2,2,4-trimethylpentyl, decyl, undecyl, dodecyl, 2-methyl-1-propyl, 2-methyl-2-propyl, 2-methyl-1-butyl, 3-methyl-1-butyl, 2-methyl-3-butyl, 2-methyl-1-pentyl, 2,2-dimethyl-1-propyl, 3-methyl-1-pentyl, 4-methyl-1-pentyl, 2-methyl-2-pentyl, 3-methyl-2-pentyl, 4-methyl-2-pentyl, 2,2-dimethyl-1-butyl, 3,3-dimethyl-1-butyl, 2-ethyl-1-butyl, and the like.

As employed throughout the description, the term “cyclic alkyl” denotes a cyclic functional group having from 3 to 10 or from 4 to 10 carbon atoms. Exemplary cyclic alkyl groups include, but are not limited to, cyclobutyl, cyclopentyl, cyclohexyl, and cyclooctyl groups.

As used herein, the term “aryl” means a monocyclic, bicyclic, or polycyclic (e.g., having 2, 3 or 4 fused rings) aromatic hydrocarbon. In some embodiments, the aryl group has from 6 to 20 carbon atoms or from 6 to 10 carbon atoms. Examples of aryl groups include, but are not limited to, phenyl, naphthyl, anthracenyl, phenanthrenyl, indanyl, indenyl, and tetrahydronaphthyl, and the like.

As used herein, the term “arylalkyl” means an alkyl group substituted by an aryl. In some embodiments, the alkyl group is a C₁₋₆ alkyl group.

As employed throughout the description, the term “alkenyl group” denotes a group which has one or more carbon-carbon double bonds and has from 2 to 18 or from 2 to 10 carbon atoms. Exemplary alkenyl groups include, but are not limited to, vinyl or allyl groups.

As used herein, the term “alkynyl” means a straight or branched alkyl group having 2 to 20 carbon atoms and one or more triple carbon-carbon bonds. In some embodiments, the alkynyl group has from 2 to 10 carbon atoms, from 2 to 8 carbon atoms, from 2 to 6 carbon atoms, or from 2 to 4 carbon atoms. Examples of alkynyl groups include, but are not limited to acetylene, 1-propylene, 2-propylene, and the like.

As used herein, the phrase “optionally substituted” means that a substitution is optional and, therefore, includes both unsubstituted and substituted atoms and moieties. A “substituted” atom or moiety indicates that any hydrogen atom on the designated compound or moiety can be replaced with a selection from the indicated substituent groups, provided that the normal valency of the designated compound or moiety is not exceeded, and that the substitution results in a stable compound. For example, if a methyl group is optionally substituted, then 1, 2, or 3 hydrogen atoms on the carbon atom within the methyl group can be replaced with 1, 2, or 3 of the recited substituent groups.

As used herein, the term “phenyl” means —C₆H₅. A phenyl group can be unsubstituted or substituted with one, two, or three suitable substituents.

As used herein, the term “cyclic alkyl” means non-aromatic cyclic hydrocarbons including cyclized alkyl, alkenyl, and alkynyl groups that have up to 20 ring-forming carbon atoms. Cycloalkyl groups have from 3 to 15 ring-forming carbon atoms, from 3 to 10 ring-forming carbon atoms, from 3 to 8 ring-forming carbon atoms, from 3 to 6 ring-forming carbon atoms, from 4 to 6 ring-forming carbon atoms, from 3 to 5 ring-forming carbon atoms, or 5 or 6 ring-forming carbon atoms. Ring-forming carbon atoms of a cycloalkyl group can be optionally substituted by oxo or sulfido. Cycloalkyl groups include, but are not limited to, monocyclic or polycyclic ring systems such as fused ring systems, bridged ring systems, and spiro ring systems. In some embodiments, polycyclic ring systems include 2, 3, or 4 fused rings. Examples of cycloalkyl groups include, but are not limited to, cyclopropyl, cyclobutyl, cyclopentyl, cyclohexyl, cycloheptyl, cyclooctyl, cyclononyl, cyclopentenyl, cyclohexenyl, cyclohexadienyl, cycloheptatrienyl, norbornyl, norpinyl, norcarnyl, adamantyl, and the like. Cycloalkyl groups can also have one or more aromatic rings fused (having a bond in common with) to the cycloalkyl ring such as, for example, benzo or thienyl derivatives of pentane, pentene, hexane, and the like (e.g., 2,3-dihydro-1H-indene-1-yl, or 1H-inden-2(3H)-one-1-yl).

As used herein, the term “halo” means halogen groups and includes, but is not limited to, fluoro, chloro, bromo, and iodo.

As used herein, the term “heterocycle” or “heterocyclic ring” means a 5- to 7-membered monocyclic or 7- to 10-membered bicyclic ring system, any ring of which may be saturated or unsaturated, and which ring consists of carbon atoms and from one to three heteroatoms chosen from N, O and S, and wherein the N and S heteroatoms may optionally be oxidized, and the N heteroatom may optionally be quaternized, and including any bicyclic group in which any of the above-defined heterocyclic rings is fused to a benzene ring. Heterocycles include rings containing one oxygen or sulfur, one to three nitrogen atoms, or one oxygen or sulfur combined with one or two nitrogen atoms. The heterocyclic ring may be attached at any heteroatom or carbon atom which results in the creation of a stable structure. Examples of heterocyclic groups include, but are not limited to, piperidinyl, piperazinyl, 2-oxopiperazinyl, 2-oxopiperidinyl, 2-oxopyrrolodinyl, 2-oxoazepinyl, azepinyl, pyrrolyl, 4-piperidonyl, pyrrolidinyl, pyrazolyl, pyrazolidinyl, imidazolyl, imidazolinyl, pyridyl, imidazolidinyl, pyrazinyl, pyrimidinyl, pyridazinyl, oxazolyl, oxazolidinyl, isoxazolyl, isoxazolidinyl, morpholinyl, thiazolyl, thiazolidinyl, isothiazolyl, quinuclidinyl, isothiazolidinyl, indolyl, quinolinyl, isoquinolinyl, benzimidazolyl, thiadiazoyl, benzopyranyl, benzothiazolyl, benzoxazolyl, furyl, tetrahydrofuryl, tetrahydropyranyl, thienyl, benzothienyl, thiamorpholinyl, thiamorpholinyl sulfoxide, thiamorpholinyl sulfone, oxadiazolyl, and the like.

Vapor phase or gas phase reactions include the exposure of the heated substrate to the precursor molecule(s) and/or co-reactants in a suitable chamber that must be capable of providing the necessary pressure control and that can also supply heat to the substrate and/or chamber walls; the chamber should also provide suitable purity for the reactions that will take place, generally through high leak integrity and the use of ultra-high purity carrier and reactive gases.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas. They may be used in conjunction with ultra-high purity carrier gases (as defined previously) and in any desired mixtures with one another (i.e., more than one type of precursor can be used either together or in discrete, independent steps to form the desired passivation layer with whatever order of precursor introduction is desired).

The precursor(s) and/or co-reactants may be delivered to the reactor using mass flow controllers (perhaps with heated lines), liquid injection vaporizers (perhaps with heated lines) or with no metering device (i.e., neat introduction of the vapor and or gas from a vessel that is isolated from the reactor using a simple valve). Any of the foregoing may also be used in combination with one another. Any means of providing the gas and/or vapor(s) to the reaction chamber that provides sufficient purity and repeatability may be used.

The precursor(s) and/or co-reactants may be introduced independently to the reactor, mixed prior to introduction to the reactor, mixed in the reactor or in any combination of the preceding in multiple, independent steps that might include differences in how the precursors are introduced between steps.

The temperature range of the reactions may be between room temperature and 400° C. In some cases, the temperature range of the reactions may be between room temperature and 200° C. In yet other cases, the temperature range of the reactions may be between room temperature and 100° C. The pressure may range from 10-10 Torr to 3000 Torr and may be maintained under dynamic flow conditions (i.e., with a valve and a butterfly valve type arrangement) or may be maintained under static conditions (i.e., an evacuated chamber is exposed to the desired precursor(s) and/or co-reactant(s) until a total desired pressure is achieved and then the chamber is isolated from both the precursor(s) and/or co-reactant(s) source(s) and the vacuum pump). The reactor can be evacuated fully and re-exposed to fresh precursor(s) and/or co-reactants as many times as necessary. Precursor(s) and/or co-reactants may be introduced using any mixtures and/or concentrations desired.

The exposure of the surface can be conducted for 0.1-60 minutes, preferably in 1-5 minutes and most preferably for 1 minute. The partial pressure of the alcohol in the reaction chamber can vary from about 1% of its saturated vapor pressure at the substrate temperature up to almost 100% of its saturation vapor pressure. Most preferably, it will be between 20 and 50% of its saturation vapor pressure. The chamber pressure can be the same as the partial pressure of the alcohol vapors but can be higher with the balance of the atmosphere comprising a carrier gas. Preferred carrier gases include N₂, He, and Ar, but also other gases such as H₂, CO₂ and dry O₂ may be used. The exposure vapors can be static (not flowing) for all or part of the exposure period. The preferred embodiment is to flow the vapors of the alcohol along with the optional carrier gas through the exposure chamber so that fresh vapors are exposed to the surface of the substrate for at least a portion of the exposure period.

The exposure chamber can be kept at near ambient temperature or can optionally be heated. Heat can be supplied to the outer walls of the chamber (hot wall) or only to the substrate (cold-wall reactor). Substrate heating in a cold wall reactor can be achieved by use of incident radiation through a transparent window (lamp heating), by resistive heating of the substrate itself or from resistive heating elements in the platform that the substrate is contacting, through induction or by other means known in the art. The temperature of the treatment is preferably between about 20° C. to about 400° C., preferably between 20° C. to about 200° C., and most preferably between 20° C. to about 100° C. The temperature can be constant during the exposure period or can vary within the specified temperature range.

Unreacted vapor of the at least one alcohol can then optionally be removed by evacuation or purging of the chamber with suitable inert gas before removing the substrate from the chamber or before chemical vapor or atomic-layer deposition processing. Optionally, the exposure chamber might also be used for subsequent processing steps to improve process efficiency so that the process may be repeated from step c), if necessary, to strip the protective film and any non-selective ALD deposit and then re-form a protective film.

The choice of the at least one alcohol and the exposing conditions used in this method should be optimized by standard experimentation to optimize selectivity of the protection afforded the silicon nitride surface against potential non-selective passivation, processing time, reagent cost, etc. depending on the requirements imposed by subsequent processing steps. For example, selectivity can be adjusted/optimized by varying the nature of the R group of the at least one alcohol having the structure represented by Formula I. Typically, since reactivity and selectivity are often inversely related, if the two surfaces are similar in chemistry, experimenting with the R group may be required to optimize the process. There is a difference in reactivity, for example between alkyl R-groups and aryl R-groups; typically, aryl groups are more reactive with active hydrogen bearing surfaces compared to alkyl groups. As a result, in some cases the alkyl groups might be needed to selectively passivate the SiN without also passivating an adjacent surface that also has less reactive active hydrogen atoms.

Once the silicon nitride surface is passivated the second surface comprising, for example, silicon oxide, is active for further selective reactions. Additional materials that may be selectively deposited on the second surface including silicon films comprising oxygen, nitrogen, hydrogen and carbon (i.e., SiOₓ, SiNₓ, SiOₓN_{y}, SiCₓN_{y}, SiOₓC_{y} all possibly incorporating H as well), metals, metal nitrides, and metal oxides. In some embodiments, a dielectric film including metal oxide or silicon oxide is selectively deposited on the second surface. In one example, the metal oxide film may serve as a cap layer on the second surface. The dielectric film can, for example, be deposited by atomic layer deposition (ALD), plasma-enhanced ALD (PEALD), chemical vapor deposition (CVD), plasma-enhanced CVD (PECVD), or pulsed CVD. According to one embodiment, the dielectric film may be selected from the group consisting of HfO₂, ZrO₂, TiO₂, Ta₂O₅, Al₂O₃, SiO₂ and a combination thereof. In some examples, the dielectric film such as metal oxide film may be deposited by ALD using alternating exposures of a volatile metal-containing precursor and an oxidizer (e.g., H₂O, H₂O₂, plasma-excited O₂ or O₃) as is detailed in U.S. provisional patent application Ser. No. 62/472,724, filed on Mar. 17, 2017, the entirety of which is incorporated herein by reference. In other examples, the dielectric film such as silicon oxide may be deposited via alternating exposures of a volatile metal-containing precursor catalyst such as trimethylaluminum, triethylaluminum, dimethylaluminum iso-propoxide, diethylaluminum iso-propoxide, and a trialkoxysilanol such as tris(tert-butoxy)silanol, tris(tert-pentoxy)silanol, bis(tert-butoxy)(tert-pentoxy)silanol, bis(tert-pentoxy)(tert-butoxy)silanol.

Selective depositions according to the present disclosure can be, for example, metal and metal oxide layers disclosed in Hamalainen et al., “Atomic Layer Deposition of Noble Metals and Their Oxides,” Chem. Mater. 2014, 26, 786-801; and Johnson et al., “A Brief review of Atomic layer Deposition: From Fundamentals to Applications”, Materials Today, Volume 17, Number 5, June 2014, both of which are incorporated herein by reference in their entireties.

In some embodiments, a metal oxide is selectively deposited on the second surface employing a metal-containing precursor. The metal-containing precursor should have sufficient vapor pressure and stable enough to be delivered into the reaction chamber, and may have a formula of M(L₁)ₓ(L₂)_{y}(L₃)_{z} wherein M is group 3 to 13 metals; L₁, L₂, and L₃ are independently selected from the group consisting of substituted or unsubstituted cyclopentadienyl, substituted or unsubstituted pyrazolyl, substituted or unsubstituted pyrollyl, substituted or unsubstituted imidazolyl, amido, alkoxy, amidinate, linear or branched diene, linear or branched alkyl, hydride, carbon monoxide, nitrosyl, halide (F, Cl, Br, I) and combination thereof; x, y, and z is 0, 1, 2, 3, 4 depending on the oxidation state of the metal. Examples of metal-containing precursors include, but not limited to, tetrakis(dimethylamino)hafnium (TDMAH), tetrakis(diethylamino)hafnium (TDEAH), tetrakis(ethylmethylamino)hafnium (TEMAH), cyclopentadienyltris(dimethylamino)hafnium (CpHf(NMe2)3), methylcyclopentadienyltris(dimethylamino)hafnium (MeCpHf(NMe2)3), ethylcyclopentadienyltris(dimethylamino)hafnium (EtCpHf(NMe2)3), cyclopentadienyltris(dimethylamino)hafnium (CpHf(NMeEt)3), methylcyclopentadienyltris(dimethylamino)hafnium (MeCpHf(NMeEt)3), tetrakis(dimethylamino)zirconium (TDMAZ), tetrakis(diethylamino)zirconium (TDEAZ), tetrakis(ethylmethylamino)zirconium (TEMAZ), cyclopentadienyltris(dimethylamino)zirconium (CpZr(NMe2)3), methylcyclopentadienyltris(dimethylamino)zirconium (MeCpZr(NMe2)3), ethylcyclopentadienyltris(dimethylamino)zirconium (EtCpZr(NMe2)3), cyclopentadienyltris(dimethylamino)zirconium (CpZr(NMeEt)3), methylcyclopentadienyltris(dimethylamino)zirconium (MeCpZr(NMeEt)3), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)molybdenum (BTBMM), bis(tert-butylimino)bis(diethylamino)molybdenum, bis(tert-butylimino)bis(ethylmethylamino)molybdenum, trimethylaluminum, triethylaluminum, dimethylaluminum iso-propoxide, diethylaluminum iso-propoxide. In other some embodiments, silicon oxide is selectively deposited on the second surface via thermal atomic layer deposition using Si(NCO)₄.

During the selective deposition process, the aforementioned protective surface previously deposited selectively on silicon nitride surfaces with the at least one alcohol could begin to react or otherwise become less inert. An optional re-application of the at least one alcohol, either with or without any of the aqueous or plasma pre-treatment steps may optionally be performed repeatedly to prevent or delay non-selective deposition on the silicon nitride surface.

In some embodiments passivation on a first surface of a substrate as described herein, such a silicon nitride surface of the substrate, relative to a second surface of the substrate is at least about 90% selective, at least about 95% selective, at least about 96%, 97%, 98% or 99% or greater selective. In some embodiments passivation only occurs on the first surface and does not occur on the second surface. In some embodiments passivation on the first surface of the substrate relative to the second surface of the substrate is at least about 70% selective, or at least about 80% selective, which may be selective enough for some particular applications. In some embodiments passivation on the first surface of the substrate relative to the second surface of the substrate is at least about 50% selective, which may be selective enough for some particular applications.

Wet chemistry cleans may be used to remove the passivation layer. Example wet chemistry cleans include acidic, basic, and oxidative (e.g., peroxide-containing) wet chemistry compositions known in the art and described above for the optional step of contacting the substrate with a wet chemical composition. Another method to remove the passivation layer is via the application of heat or other energy.

### Examples

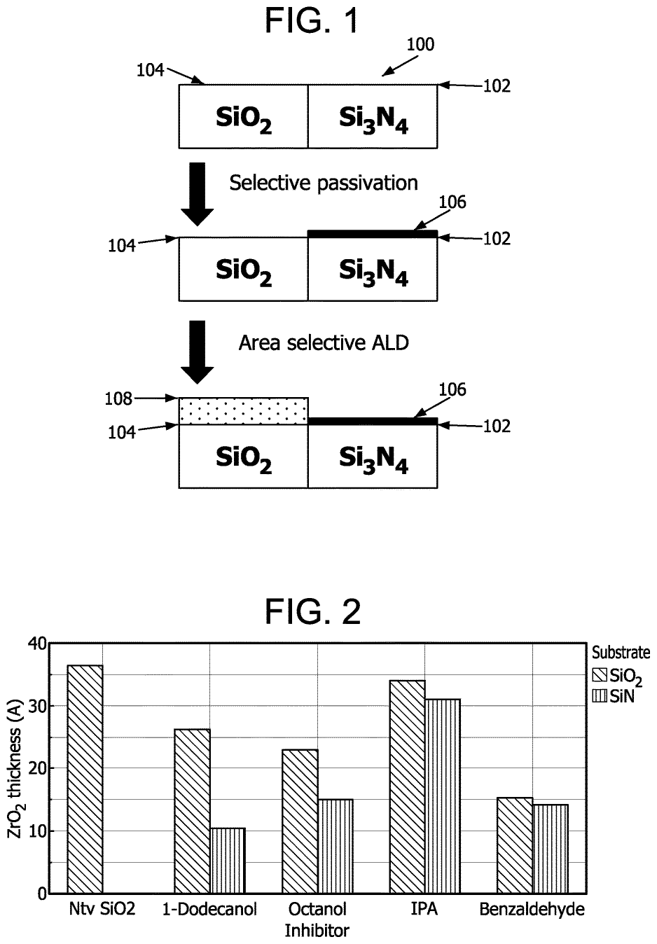

Example embodiments show alcohols (alkyl alcohols or aryl alcohols) selectively passivate the silicon nitride (Si₃N₄) surface versus the silicon oxide (SiO₂) surface. This process is depicted in FIG. 1. The process results in the selectivity to grow thicker metal film (or metal nitride film) on SiO₂.

A substrate 100 containing a first surface 102 (Si₃N₄) and a second surface 104 (SiO₂). Expose substrates to alkyl alcohol or aryl alcohol inhibitor to form a passivated region 106, preferably a self-assembled monolayer (SAM), to selectively passivate the Si₃N₄ surface 102 by converting the Si—NH₂ groups to aliphatic or aromatic groups. Subsequently a dielectric film 108 is deposited on the second surface 104.

### Dielectrics on Dielectrics (DoD)

CVD silicon nitride (Si₃N₄) and thermal silicon oxide (SiO₂) are used to as growth and non-growth substrates to test the passivation ability of the new chemistries. The thin organic passivation layer is formed by dipping the substrates in the toluene solution at 10 mM concentration at 60 C overnight. Prior to dipping, the as-received SiN and SiO₂ substrate are etched in diluted HF at 100:1 concentration for 1 minute to remove the SiON and native oxide layer on the substrate respectively. After pre-clean, SiN and SiO₂ surfaces become hydrophilic as confirmed by water contact of 27 and zero degree. The low contact angle indicates the formation of NHx and OH terminated surfaces with differentiate functionalities. The SAM solution is prepared by dissolving chemicals in toluene to have solutions of different concentrations.

Four different representative passivation chemistries are selected to demonstrate the passivation capabilities, and Cp₂ZrMe(OMe) and water ALD process was used to test the passivation layer inhibition ability towards ALD precursor and reactant adsorption and reactions. The ALD deposition is performed at 250° C. for high quality metal oxide film depositions.

The passivation chemistries test is listed as follows: 1-dodecanol, a representative family of molecules with alcohol head group; 1-octanol, a representative molecule with alcohol head group and short chain; isopropyl alcohol, a representative molecule with alcohol and shortest hydrocarbon chain; and benzaldehyde, a representative molecule with aldehyde head group.

FIG. 2 shows the ALD nucleation inhibition ability of three different passivation chemistries. In agreement with WCA observation, dodecanol passivation SiN shows better ZrO₂ deposition selectivity than other two chemistries, and the loss of selectivity during ALD deposition for benzaldehyde is believed due to its low thermal stability at 250° C., which causes degradation of passivation layer resulting in reduction of ALD deposition inhibition. Annealing the dodecanol passivation SiN in N₂ environment for 1 hr at 250° C. shows no degradation of passivation layer quality and WCA slightly increases after annealing due to desorption of physisorbed species, which leads to better passivation layer quality. The deposition nucleation inhibition of alcohol passivation layer shows some dependence on the chain length, shorter hydrocarbon chain does not show good selectivity in deposition film.

FIG. 2 illustrates selective growth of ZrO₂ on passivated SiN and SiO2 using different chemistries. For purposes of this disclosure and claims selectivity of the second surface to the first surface if found by the following equation: selectivity=(thickness of film on the second surface (SiO₂)−thickness of film on the first surface (Si₃N₄))/(thickness of film on the second surface (SiO₂)+thickness of film on the first surface (Si₃N₄)). Notably, successful selectivity (preferably greater than about 0.1, more preferably greater than about 0.2, and most preferably greater than about 0.3) is achieved by passivating with 1-dodecanol and 1-octanol. Passivating with isopropyl alcohol and benzaldehyde were significantly less successful.

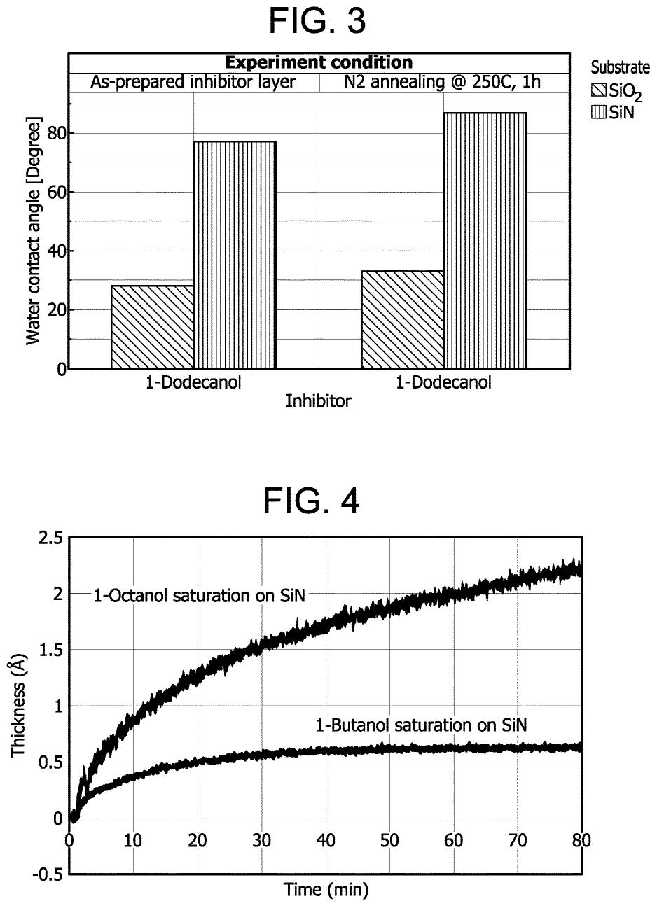

FIG. 3 illustrates good thermal stability of alcohol passivated SiN after 250° C. annealing.

TABLE 1
Selectivity of different inhibitors

| | | | Selectivity |
|---|---|---|---|
| | | | (ZrO₂ (Å) on SiO₂ − |
| | | | Ru(Å) on SiN)/(ZrO₂ |
| | ZrO₂ (Å) on | ZrO₂ (Å) on | (Å) on SiO₂ + ZrO₂ |
| Inhibitor molecule | SIN | SiO₂ | (Å) on SiN) |
| No inhibitor | 36.5 | 36.5 | 0 |
| 1-Octanol | 12.4 | 23.5 | 0.43 |
| 1-Dodecanol | 10.4 | 26.2 | 0.31 |
| Iso-propyl alcohol | 30.4 | 34.5 | 0.06 |
| Benzaldehyde | 14.2 | 15.3 | 0.04 |

As shown in Table 1, successful selective deposition of dielectric films (ZrO₂ at greater than about 0.3 selectivity) was achieved using various primary alcohols: 1-octanol, and 1-dodecanol while smaller alkyl alcohol such as iso-propyl alcohol and prior art inhibitor such as benzaldehyde show much less selectivity, demonstrating linear alcohols with C₄ to C₁₈ linear alkyl group, preferably C₆ to C₁₈ linear alkyl group, most preferable C₈ to C₁₈ linear alkyl group are suitable inhibitors for selective deposition of dielectric film on silicon oxide vs silicon nitride.

Two distinct representative passivation chemistries have been chosen to showcase the passivation capabilities among R—OH structures where R is linear alkyl group. The passivation layer inhibition ability towards ALD process was tested using Si(NCO)₄, triethylamine, and water ALD process. The ALD deposition was conducted at 100° C. to achieve silicon oxide film deposition.

The passivation chemistries are among alcohols head groups; 1-butanol for the short hydrocarbon chain alcohol test, and 1-octanol for the long hydrocarbon chain alcohol test.

FIG. 4 illustrates the saturation of two passivation chemistries. It is apparent that 1-octanol demonstrated greater reactivity with SiN surface compared to 1-butanol. This led to the formation of a superior passivation layer on SiN surface, resulting in reduced growth of SiO₂ in the subsequent step. Applying the same inhibition chemistries on a silicon oxide substrate yielded no formation of a passivation layer. This led to immediate growth of SiO₂ on the silicon oxide surface, underscoring the selectivity of the proposed inhibitors.

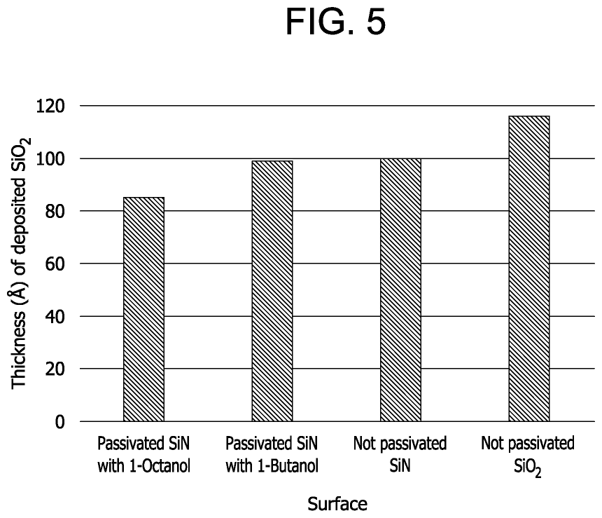

FIG. 5 demonstrates the selective growth of silicon oxide on passivated SiN and SiO₂ using 1-butanol and 1-octanol. The thickness of SiO₂ deposited on the passivated silicon nitride substrate is less than a thickness of SiO₂ deposited on the passivated silicon oxide substrate. However, passivating with 1-butanol was significantly less successful. This confirms the essential role of the hydrocarbon chain length in the inhibitor for passivation.

While the principles of the disclosure have been described above in connection with preferred embodiments, it is to be clearly understood that this description is made only by way of example and not as a limitation of the scope of the claimed subject matter.

We claim:

1. A method for selectively passivating a surface of a substrate, wherein the surface of the substrate comprises at least a first surface comprising silicon nitride and at least a second surface comprising a material other than silicon nitride, the method comprising the steps of:
a. optionally, treating the surface with hydrogen plasma, argon plasma, or ammonia plasma;
b. exposing the surface to at least one alcohol having a structure according to Formula I:
R—OH (I),
wherein R is selected from the group consisting of a substituted or unsubstituted C₅ to C₁₈ linear alkyl group, a substituted or unsubstituted branched C₄ to C₁₈ alkyl group, a substituted or unsubstituted C₄ to C₈ cyclic alkyl group, a substituted or unsubstituted C₃ to C₁₀ heterocyclic group, a substituted or unsubstituted C₄ to C₁₈ alkenyl group, a substituted or unsubstituted C₄ to C₁₈ aryl group, a substituted or unsubstituted C₈ to C₂₀ arylalkyl group, and a substituted or unsubstituted C₄ to C₁₀ alkynyl group, and wherein the at least one alcohol selectively reacts with the silicon nitride to passivate the first surface thereby leaving the second surface substantially unreacted; and
c. depositing a dielectric film onto the substrate via atomic layer deposition.

2. The method of claim 1, further comprising the following steps which are performed prior to steps a and b:
contacting the surface of the substrate with a wet chemical composition;
rinsing the surface with deionized water; and
drying the surface;
wherein the wet chemical composition comprises at least one selected from the group consisting of a composition comprising H₂O₂(28% aq.), NH₄O₄(28-30%), and H₂O; HF (0.01%-5% (aq.)); peroxide; RCA clean chemicals SC-1 and SC-2; and a mixture of H₂SO₄/H₂O₂.

3. The method of claim 1, wherein the second surface comprises at least one selected from the group consisting of SiO₂, carbon doped silicon oxide, a metal oxide, copper, cobalt, tungsten, amorphous silicon, polysilicon, monocrystalline silicon, germanium, and amorphous hydrogenated germanium.

4. The method of claim 3, wherein the second surface comprises SiO₂ or carbon doped silicon oxide

5. The method of claim 1, wherein the at least one alcohol is a C₅ to C₁₈ linear alkyl group having a structure CₙH₂ₙ₊₁, wherein n is 5 to 18.

6. The method of claim 5, wherein the at least one alcohol is a linear C₈ to C₁₈ alcohol selected from the group consisting of 1-octanol, 1-nonanol, 1-decanol, 1-undecanol, 1-dodecanol, 1-tridecanol, 1-tetradecanol, 1-pentadecanol, 1-hexadecanol, 1-heptadecanol, 1-octadecanol, 8-chloro-1-octanol, and pentadecafluoro-1-octanol.

7. The method of claim 1, wherein R is a branched C₄ to C₁₈ alkyl group having a formula CₙH₂ₙ₊₁, wherein n is 4 to 18.

8. The method of claim 7, wherein the at least one alcohol is selected from the group consisting of iso-butyl alcohol, iso-pentyl alcohol, iso-hexyl alcohol, iso-heptyl alcohol, iso-octyl alcohol, iso-nonyl alcohol, iso-decyl alcohol, iso-undecyl alcohol, iso-dodecyl alcohol, iso-tridecyl alcohol, iso-tetradecyl alcohol, iso-pentadecyl alcohol, iso-hexadecyl alcohol, iso-heptadecyl alcohol, and iso-octadecyl alcohol.

9. The method of claim 1, wherein R is a substituted or unsubstituted C₃ to C₈ cyclic alkyl group.

10. The method of claim 9, wherein the at least one alcohol is selected from the group consisting of cyclopropyl alcohol, cyclobutyl alcohol, cyclopentyl alcohol, cyclohexyl alcohol, cycloheptyl alcohol, cyclooctyl alcohol, and 1-methyl cyclohexanol.

11. The method of claim 1, wherein R comprises a substituted or unsubstituted C₄ to C₁₈ aryl group.

12. The method of claim 11, wherein the at least one alcohol is selected from the group consisting of phenol, p-cresol, 4-methyphenol, 4-ethylphenol, 4-n-propylphenyl, 4-iso-propylphenyl, 4-n-butylphenyl, 4-sec-butylphenyl, 4-iso-butylphenyl, 4-trifluoromethylphenol, 4-hexyl-phenol, 4-n-octyl-phenol, and 4-n-pentyl-phenol.

13. The method of claim 1, wherein R is an unsubstituted C₈ to Cis linear alkyl group or R is a substituted or unsubstituted branched C₃ to C₁₈ alkyl group.

14. The method of claim 13, wherein the at least one alcohol is selected from the group consisting of 1-octanol, 1-nonanol, 1-decanol, 1-undecanol, 1-dodecanol, 1-tridecanol, 1-tetradecanol, 1-pentadecanol, 1-hexadecanol, 1-heptadecanol, 1-octadecanol, 8-chloro-1-octanol, pentadecafluoro-1-octanol, iso-butyl alcohol, iso-pentyl alcohol, iso-hexyl alcohol, iso-heptyl alcohol, iso-octyl alcohol, iso-nonyl alcohol, iso-decyl alcohol, iso-undecyl alcohol, iso-dodecyl alcohol, iso-tridecyl alcohol, iso-tetradecyl alcohol, iso-pentadecyl alcohol, iso-hexadecyl alcohol, iso-heptadecyl alcohol, and iso-octadecyl alcohol.

15. The method of claim 1, wherein R is a substituted or unsubstituted C₅ to C₂₀ arylalkyl group.

16. The method of claim 15, wherein the at least one alcohol is benzyl alcohol.

17. (canceled)

18. A method of selectively depositing a film on a surface of a substrate wherein the surface of the substrate comprises at least a first surface comprising silicon nitride and at least a second surface comprising a material other than silicon nitride, the method comprising the steps of:
a. optionally, treating the surface with hydrogen plasma or ammonia plasma;
b. exposing the surface to at least one alcohol having a structure according to Formula I:
R—OH (I),
wherein, R is selected from the group consisting of a substituted or unsubstituted C₅ to C₁₈ linear alkyl group, a substituted or unsubstituted branched C₂ to C₁₈ alkyl group, a substituted or unsubstituted C₃ to C₈ cyclic alkyl group, a substituted or unsubstituted C₃ to C₁₀ heterocyclic group, a substituted or unsubstituted C₃ to C₁₈ alkenyl group, a substituted or unsubstituted C₄ to C₁₈ aryl group, a substituted or unsubstituted C₅ to C₂₀ arylalkyl group, and a substituted or unsubstituted C₃ to C₁₀ alkynyl group, wherein the at least one alcohol selectively reacts with the silicon nitride to passivate the first surface thereby leaving the second surface substantially unreacted; and
c. exposing the surface of the substrate to one or more deposition precursors to deposit a dielectric film on the second surface selectively over the first surface.

19.-23. (canceled)

24. The method of claim 18, wherein the dielectric film comprises TiO₂, HfO₂, ZrO₂, Al₂O₃ Ta₂O₅, SiO₂ or combinations thereof.

25.-36. (canceled)

37. The method of claim 1, wherein the R in formula (I) is R′—CH₂, wherein R′ is chosen from the group consisting of linear C₇ to C₁₇ alkyl groups, branched C₆ to C₁₆ alkyl groups, and C₆ to C₁₀ aryl groups.

38. The method of claim 1, further comprising
wherein a thickness of dielectric film deposited on the first surface is less than a thickness of dielectric film deposited on the second surface;
wherein the second surface comprises silicon dioxide; and
wherein a deposition selectivity of the second surface to the first surface is greater than about 0.1, more preferably greater than about 0.2, and most preferably greater than about 0.3.

39. (canceled)

40. The method of claim 1, wherein R comprises a fluorine-substituted C₄ to C₁₈ linear alkyl group having a structure CₙF₂ₙ₊₁CH₂—OH, wherein n is 1 to 17.

41. The method of claim 40, wherein the at least one alcohol is selected from the group consisting of C₃F₇CH₂—OH, C₄F₉CH₂—OH, C₅F₁₁CH₂—OH, C₆F₁₃CH₂—OH, C₇F₁₅CH₂—OH, C₈F₁₇CH₂—OH, and C₉F₁₉CH₂—OH.

42. The method of claim 1, wherein R is a chlorine-substituted C₁ to C₁₈ linear alkyl group having a structure CₙCl₂ₙ₊₁CH₂—OH, wherein n is 1 to 17.

43. The method of claim 42, wherein the at least one alcohol is selected from the group consisting of CCl₃CH₂—OH, C₂Cl₅CH₂—OH, C₃Cl₇CH₂—OH, C₄Cl₉CH₂—OH, C₅Cl₁₁CH₂—OH, C₆Cl₁₃CH₂—OH, C₇Cl₁₅CH₂—OH, C₈Cl₁₇CH₂—OH, C₉Cl₁₉CH₂—OH, and 8-chloro-1-octanol.

44. (canceled)

45. The method of claim 15, wherein the at least one alcohol is selected from the group consisting of phenylmethanol, 2-phenyl-1-ethanol, 3-phenyl-1-propanol, 4-phenyl-1-butanol, 5-phenyl-1-pentanol, 6-phenyl-1-hexanol, 7-phenyl-1-heptanol, 8-phenyl-1-octanol, and combinations thereof.

46. The method of claim 18, wherein the dielectric film is silicon oxide deposited using a precursor comprising Si(NCO)₄.

47. The method of claim 46, wherein a thickness of dielectric film deposited by Si(NCO)₄ on the first surface is less than a thickness of silicon oxide film deposited on the second surface;
wherein the first surface comprises silicon nitride; and
wherein the second surface comprises silicon dioxide; and
wherein the at least one alcohol is 1-octanol.

48. The method of claim 47, wherein a deposition selectivity of the second surface relative to the first surface is greater than approximately 0.2.
